(19) United States
(12) Patent Application Publication
(10) Pub. No.: US 2009/0001581 A1
(43) Pub. Date: Jan. 1, 2009

(54) METAL LINE OF SEMICONDUCTOR DEVICE AND METHOD OF FORMING THE SAME

(76) Inventors: Eun Soo KIM, Incheon (KR); Cheol Mo Jeong, Icheon-si (KR); Seung Hee Hong, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/951,245

(22) Filed: Dec. 5, 2007

(30) Foreign Application Priority Data
Jun. 28, 2007 (KR) 10-2007-64505

(51) Int. Cl. H01L 23/52; H01L 21/4763

(52) U.S. Cl. 257/751; 438/653; 257/E23.141; 257/E21.495

(57) ABSTRACT

A metal line of a semiconductor device includes an insulating layer in which damascene patterns have been formed, a first metal layer formed on sidewalls and bottom surfaces of the damascene patterns, a second metal layer formed on the first metal layer within the damascene patterns and having a lower resistance than the first metal layer, and a third metal layer formed on the second metal layer.

### CROSS-REFERENCES TO RELATED APPLICATIONS

The present application claims priority to Korean patent application number 10-2007-64505, filed on Jun. 28, 2007, which is incorporated by reference in its entirety.

### BACKGROUND OF THE INVENTION

The present invention relates to a metal line of a semiconductor device and a method of forming the same and, more particularly, to a metal line of a semiconductor device and a method of forming the same, in which the resistance of the metal line can be reduced.

In general, a semiconductor device includes a plurality of transistors. The transistors have gates connected to a metal line and are operated according to voltage applied thereto. The metal line, which has a direct influence on the operation of the device, requires a very low resistivity to transfer the voltage within a short period of time. However, in recent years, the level of integration of semiconductor devices continuously increases. As the level of integration increases, the width of the metal line decreases.

If the width of the metal line decreases, an area (the cross section of the metal line) through which current can pass also decreases. Thus, even if the same voltage is applied, the resistivity of the metal line increases. If the resistivity of the metal line is increased, a friction force applied to electrons in the metal line also increases, resulting in heating of the metal line.

If the resistivity of the metal line increases, the transfer time of current is delayed and heat is generated in the metal line. Consequently, the increased metal line resistivity may shorten the lifespan of the semiconductor device.

### BRIEF SUMMARY OF THE INVENTION

The present invention is directed toward a metal line of a semiconductor device and a method of forming the same. The metal line includes a first metal layer, a second metal layer, and a third metal layer. The content of the second metal layer having a resistivity lower than that of the first and third metal layers is greater than the content of the first and third metal layers, thereby reducing resistivity of the metal line.

Furthermore, the present invention is directed toward the prevention of the occurrence of an abnormal interface by protecting the circumference of the second metal layer with the first and third metal layers, and improving electrical characteristics of the metal line by reducing damage caused by a polishing process.

In one embodiment, a metal line of a semiconductor device includes an insulating layer in which damascene patterns have been formed, a first metal layer formed on sidewalls and bottom surfaces of the damascene patterns, a second metal layer formed on the first metal layer within the damascene patterns and having a lower resistance than the first metal layer, and a third metal layer formed on the second metal layer.

A barrier layer is formed between the damascene patterns and the first metal layer. The barrier layer is formed of titanium (Ti). The second metal layer is formed of aluminum (Al).

The first metal layer is formed from material that does not react to the barrier layer or the second metal layer. The first metal layer and the third metal layer are formed of tungsten (W).

In another embodiment, a method of forming a metal line of a semiconductor device includes forming an insulating layer on a semiconductor substrate. Damascene patterns are formed in the insulating layer. A first metal layer is formed on sidewalls and at bottoms of the damascene patterns. A second metal layer with a low resistance is deposited on the first metal layer within the damascene patterns. A third metal layer is formed on the first metal layer, the second metal layer, and the insulating layer. A polishing process is performed to expose the insulating layer.

The insulating layer is formed from a material having a low dielectric constant. Before the formation of the first metal layer, a barrier layer is formed along a surface of the semiconductor substrate in which the damascene patterns have been formed.

The barrier layer is formed from titanium (Ti), and the first metal layer is formed by a physical vapor deposition (PVD) method.

The first metal layer is formed of tungsten (W). The first metal layer is formed to a thickness of approximately 10 to 20 angstroms on the sidewalls of the damascene patterns. The second metal layer is formed on the insulating layer in which the first metal layer has been formed, and an annealing process is performed so that the second metal layer flows into the damascene patterns. The annealing process is performed at a temperature of approximately 430 to 450 degrees Celsius. The first metal layer, the second metal layer, and the third metal layer are formed within each damascene pattern.

The second metal layer has a height, which is approximately 10% to 20% lower than that of the damascene patterns. The second metal layer is formed from aluminum (Al).

The second metal layer is formed to have a thickness of approximately 200 to 300 angstroms. The second metal layer is formed by a chemical vacuum deposition (CVD) method. The third metal layer is formed to have a thickness of approximately 1000 to 2000 angstroms.

A capping layer is formed on the insulating layer before the formation of the damascene patterns.

### BRIEF DESCRIPTION OF THE DRAWINGS

FIG. 1 is a graph illustrating a change of resistivity depending on the width of a metal line; and

FIGS. 2A to 2I are cross-sectional views illustrating a method of forming a metal line of a semiconductor device according to the present invention.

### DESCRIPTION OF SPECIFIC EMBODIMENTS

Specific embodiments according to the present patent will be described with reference to the accompanying drawings.

FIG. 1 is a graph illustrating a change of resistivity depending on the width of a metal line.

Referring to FIG. 1, a metal line used in a semiconductor device has a characteristic in that resistivity varies depending on line width. In a conventional semiconductor device having a wide line width of approximately 120 nm to 70 nm, tungsten (W) is generally used for the metal line. Tungsten (W) is used as the metal line because it has a low resistivity and performs well at high temperatures. In recent years, however, as the level of integration of semiconductor devices has increased, the width of the metal line has decreased (approximately 60 nm to 30 nm) and the resistivity of the metal line has increased. In particular, the resistivity of tungsten (W) abruptly increases as the width of the metal line decreases.

Such an increase in resistivity may hinder the improvement of the level of integration of semiconductor devices. Thus, a material having a lower resistivity than tungsten (W) is used to form the metal line having a narrow width.

From the graph of FIG. 1, it can be seen that aluminum (Al) and copper (Cu) have a lower resistivity than tungsten (W) at a narrow line width of 60 nm to 30 nm. Copper (Cu) has a lower resistivity than aluminum (Al) and has a small increasing rate of resistivity when the line width is narrowed. Accordingly, copper (Cu) has better electrical characteristics than aluminum (Al). However, when copper (Cu) is exposed to oxygen, oxidization proceeds rapidly. Accordingly, a problem arises because resistivity due to oxidization can rapidly increased.

In contrast, aluminum (Al) does not easily react with oxygen, but has weak physical properties. Thus, if a chemical mechanical polishing (CMP) process is performed on aluminum (Al), the surface of aluminum (Al) becomes very rough or is likely to be damaged by a slurry used in the CMP process.

Accordingly, in the present invention, in order to lower the resistivity of the metal line, aluminum (Al) with a lower resistivity than tungsten (W) is used for the metal line. Tungsten (W) having a thin thickness is formed on the circumference of aluminum (Al) with weak physical properties in order to protect the aluminum (Al). The metal line of the semiconductor device and a method of forming the same are described below in detail.

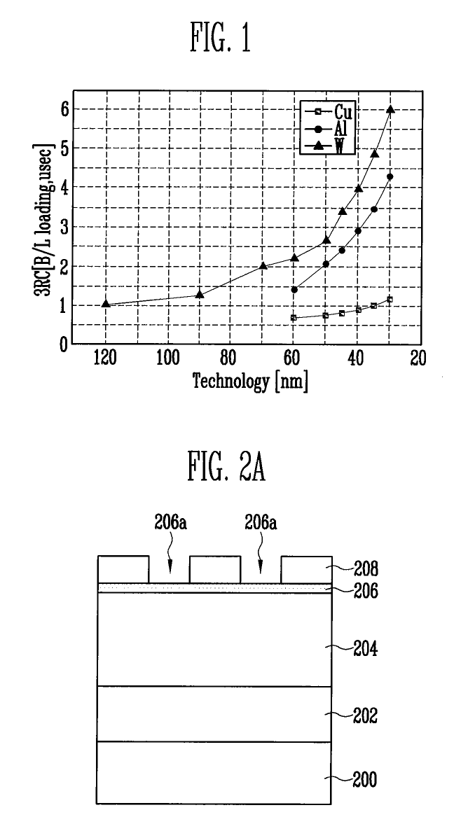

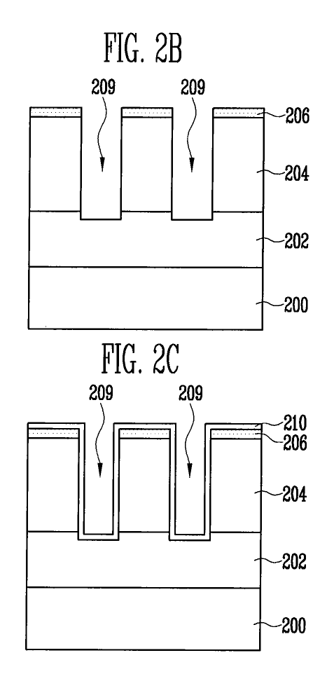

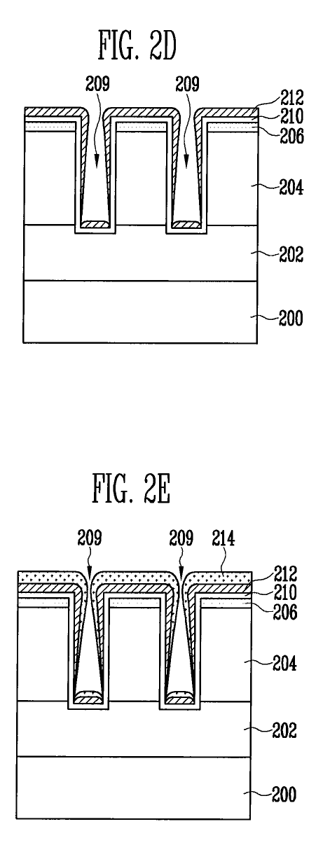

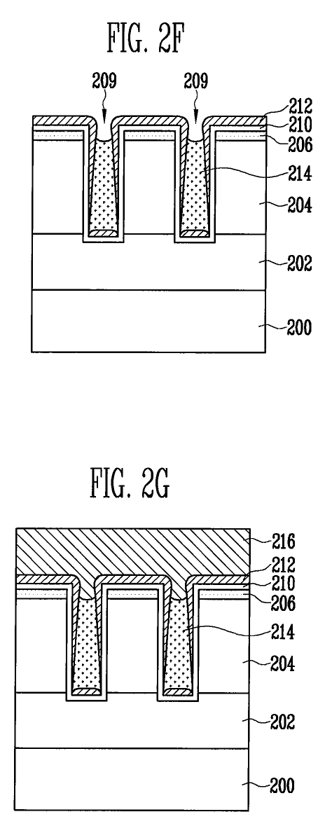

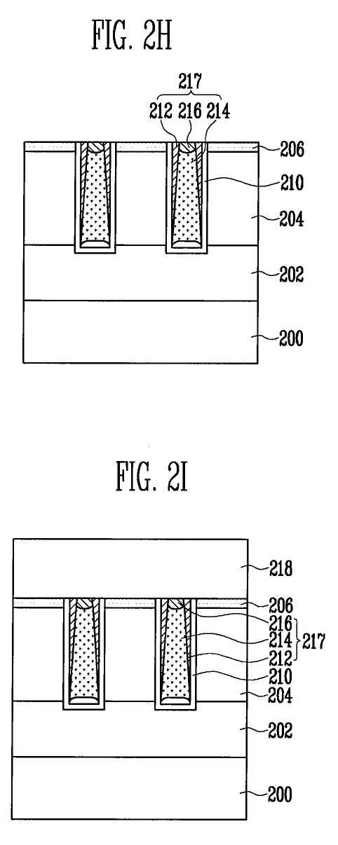

FIGS. 2A to 2I are cross-sectional views illustrating a method of forming a metal line of a semiconductor device according to the present invention.

Referring to FIG. 2A, a first insulating layer 202 for an interlayer insulating layer is formed on a semiconductor substrate 200 in which transistors (not shown) are formed. The first insulating layer 202 can be formed from an oxide layer. A second insulating layer 204 and a capping layer 206 are formed over the semiconductor substrate 200 on which the first insulating layer 202 has been formed to perform a damascene process. The second insulating layer 204 can be formed of a low dielectric (k) material. The capping layer 206 can be formed of a SiCN film. The process of forming the capping layer 206 may be omitted, but it is preferably formed because the capping layer 206 can protect the first insulating layer 202 in a subsequent etch process. A hard mask film (not shown) and a photoresist film (not shown) are formed over the capping layer 206. A photolithography process is then performed to pattern the photoresist film (not shown) such that open regions 206a are formed in regions where metal lines will be formed. The hard mask film is patterned according to the patterned photoresist film (not shown) to form a hard mask pattern 208. The patterned photoresist film (not shown) is then removed.

Referring to FIG. 2B, an etch process is performed along the hard mask pattern (refer to 208 in FIG. 2A) to pattern the capping layer 206 and the second insulating layer 204, thereby forming damascene patterns 209 such as trenches or holes. The etch process is performed so that the first insulating layer 202 is partially exposed at the bottoms of the damascene patterns 209. Though not shown in the drawings, the damascene patterns 209 are formed in the regions where the transistors (not shown) have been formed such that top surfaces of the transistors (not shown) are exposed. After the damascene patterns 209 are formed, the hard mask pattern (refer to 208 in FIG. 2A) is removed.

Referring to FIG. 2C, a barrier layer 210 is formed along the surface of the semiconductor substrate 200 over which the damascene patterns 209 are formed in order to protect the surfaces of the first insulating layer 202 and the second insulating layer 204 within the damascene patterns 209. The barrier layer 210 also increases an adhesive property with a subsequently formed metal layer. The barrier layer 210 can be formed of liner metal having a thin thickness, such as titanium (Ti).

Referring to FIG. 2D, a first metal layer 212 for the metal line is formed over the semiconductor substrate 200 over which the barrier layer 210 has been formed. The first metal layer 212 functions as a passivation layer to prevent the barrier layer 210, formed of titanium (Ti), and a subsequent aluminum (Al) film from contacting each other.

Specifically, if the aluminum (Al) film and the titanium (Ti) film are brought in contact with each other, a chemical reaction occurs between the two films. A TiAl₃ film may be formed due to the chemical reaction. The TiAl₃ film may serve as an abnormal interface causing diffusion. This may degrade electrical characteristics of the metal line.

To prevent this problem, the first metal layer 212 is preferably formed of tungsten (W). Tungsten (W) does not react with the titanium (Ti) film and the aluminum (Al) film. Furthermore, tungsten (W) does not form a new interface. Thus, tungsten (W) is suitable for the first metal layer 212.

However, since tungsten (W) has a higher resistivity than aluminum (Al), it is preferred that the first metal layer 212 be formed as thin as possible in order to lower the resistivity of the metal line.

To this end, the first metal layer 212 is preferably formed by a physical vapor deposition (PVD) method with poor step coverage. If the first metal layer 212 is formed along the surface of the barrier layer 210 by the PVD method, the first metal layer 212 is formed with a relatively large thickness on the top surfaces of projected regions of the second insulating layer 204 and at the bottoms of the damascene patterns 209. The first metal layer 212 having a relatively small thickness is formed on the sidewalls of the damascene patterns 209. For example, the first metal layer 212 having a thickness of approximately 10 to 20 angstroms is formed on the sidewalls of the damascene patterns 209. The first metal layer 212 is formed at the bottoms of the damascene patterns 209 to have a thickness at least as thick as the thickness of the first metal layer 212 formed on the sidewalls of the damascene patterns 209. Consequently, the sidewalls and bottoms of the damascene patterns 209 are covered with the first metal layer 212.

Alternatively, if the first metal layer 212 is formed by a chemical vapor deposition (CVD) method with good step coverage, the first metal layer 212 is formed not only at the bottoms of the damascene patterns 209, but also on the sidewalls of the damascene patterns 209. The first metal layer 212 increases the volume of tungsten (W) with a high resistivity. Thus, a space where aluminum (Al) with a relatively low resistivity will be formed is narrowed thereby making it difficult to effectively lower the resistivity of the metal line.

For this reason, the first metal layer 212 is preferably formed by a PVD method with poor step coverage.

Referring to FIG. 2E, a second metal layer 214 for the metal line is formed within the damascene patterns 209 having the first metal layer 212 formed therein. The second metal layer 214 may be formed of aluminum (Al) to lower the resistivity of the metal line. The second metal layer 214 can be formed to a thickness of approximately 200 to 300 angstroms by a CVD method.

The second metal layer 214 can be formed to fill the inside of the damascene pattern 209. However, the inside of the damascene patterns 209 is not easily filled because a top width of the damascene patterns 209 is narrowed by the first metal layer 212. Thus, the second metal layer 214 is first formed on the first metal layer 212 and a subsequent annealing process is then performed to fill the inside of the damascene patterns 209. This is described below with reference to the drawings.

Referring to FIG. 2F, an annealing process of melting the second metal layer 214 to fill the damascene patterns 209 is carried out. The annealing process can be performed at a temperature of approximately 430 to 450 degrees Celsius. If the annealing process is carried out, the second metal layer 214 is melted and flows into the damascene patterns 209. Thus, the annealed second metal layer 214 fills the damascene patterns 209.

The height of the second metal layer 214 to fill the inside of the damascene patterns 209 can be lower than the top surface of the damascene patterns 209. However, when the height of the second metal layer 214 is the same as or higher than that of the damascene patterns 209, an etch process may be performed to lower the height of the second metal layer 214 relative to the height of the damascene patterns 209. For example, the height of the second metal layer 214 can be controlled so that it is lower than the height of the damascene patterns 209 by approximately 10% to 20%.

Referring to FIG. 2G, a third metal layer 216 for the metal line is formed over the semiconductor substrate 200 in which the second metal layer 214 fills the damascene patterns (refer to 209 in FIG. 2F). The third metal layer 216 protects a top surface of the second metal layer 214 formed of the aluminum (Al) film.

Specifically, if a CMP process is performed to expose the aluminum (Al) film, the surface of the aluminum (Al) film may be damaged by slurry used in the polishing process. For this reason, an adhesive property between the metal line and a film formed on the metal line, and electrical characteristics of the metal line can be degraded. Thus, the third metal layer 216 is formed on the second metal layer 214 formed of aluminum (Al) to protect the second metal layer 214 from damage during a CMP process.

The third metal layer 216 can be formed of tungsten (W). The tungsten (W) film can be formed by a CVD method to easily cover the exposed second metal layer 214. The third metal layer 216 can be formed to a thickness of approximately 1000 to 2000 angstroms to sufficiently cover the second metal layer 214.

Referring to FIG. 2H, a CMP process is performed to expose the capping layer 206, so that the first metal layers 212, the second metal layers 214, and the third metal layers 216 formed in the respective damascene patterns (refer to 209 in FIG. 2F) are isolated from each other. Thus, the first metal layer 212, the second metal layer 214, and the third metal layer 216 formed within each damascene pattern (refer to 209 in FIG. 2F) become a metal line 217.

Referring to FIG. 2I, a third insulating layer 218 is formed over the semiconductor substrate 200 in which the metal line 217 has been formed. The third insulating layer 218 can be formed of an oxide layer.

If the metal line 217 is formed as described above, about 80% of the metal line 217 can be formed using aluminum (Al) with a low resistivity. It is therefore possible to lower the resistivity of the metal line 217. Furthermore, since the circumference of aluminum (Al) is protected by tungsten (W), the occurrence of an abnormal interface and damage to the surface of the aluminum (Al) film can be prevented.

In accordance with the present invention, the metal line is comprised of the first metal layer, the second metal layer, and the third metal layer. The content of the second metal layer with a lower resistivity than the first and third metal layers is greater than the content of the first and third metal layers. Accordingly, the resistivity of the metal line can be reduced.

Furthermore, since the circumference of the second metal layer is protected by the first and third metal layers, the occurrence of an abnormal interface can be prevented and damage due to a polishing process can be reduced. Accordingly, electrical characteristics of the metal line can be improved.

Although the foregoing description has been made with reference to specific embodiments, it is to be understood that changes and modifications may be made by one having ordinary skill in the art without departing from the spirit and scope of the present invention and appended claims.

What is claimed is:

1. A metal line of a semiconductor device, the metal line comprising:
an insulating layer in which damascene patterns have been formed;
a first metal layer formed over sidewalls and bottom surfaces of the damascene patterns;
a second metal layer formed over the first metal layer within the damascene patterns and having a lower resistance than the first metal layer; and
a third metal layer formed over the second metal layer.

2. The metal line of the semiconductor device of claim 1, wherein a barrier layer is formed between the damascene patterns and the first metal layer.

3. The metal line of the semiconductor device of claim 2, wherein the barrier layer is formed of titanium (Ti).

4. The metal line of the semiconductor device of claim 1, wherein the second metal layer is formed of aluminum (Al).

5. The metal line of the semiconductor device of claim 2, wherein the first metal layer is formed from material that does not react to the barrier layer or the second metal layer.

6. The metal line of the semiconductor device of claim 5, wherein the first metal layer and the third metal layer are formed of tungsten (W).

7. A method of forming a metal line of a semiconductor device, the method comprising:
forming an insulating layer over a semiconductor substrate;
forming damascene patterns in the insulating layer;
forming a first metal layer over sidewalls and over bottoms of the damascene patterns;
depositing a second metal layer with a low resistance over the first metal layer within the damascene patterns;
forming a third metal layer over the first metal layer, the second metal layer, and the insulating layer; and
performing a polishing process to expose the insulating layer.

8. The method of claim 7, wherein the insulating layer is formed from material having a low dielectric constant.

9. The method of claim 7, further comprising, before forming the first metal layer, forming a barrier layer over a surface of the semiconductor substrate in which the damascene patterns have been formed.

10. The method of claim 9, wherein the barrier layer is formed from titanium (Ti).

11. The method of claim 7, wherein the first metal layer is formed by a physical vapor deposition (PVD) method.

12. The method of claim 7, wherein the first metal layer is formed of tungsten (W).

13. The method of claim 7, wherein the first metal layer is formed to a thickness of approximately 10 to 20 angstroms over the sidewalls of the damascene patterns.

14. The method of claim 7, wherein depositing the second metal layer comprises:
forming the second metal layer over the insulating layer in which the first metal layer has been formed; and
performing an annealing process so that the second metal layer flows into the damascene patterns.

15. The method of claim 14, wherein the annealing process is performed at a temperature of approximately 430 to 450 degrees Celsius.

16. The method of claim 14, wherein the first metal layer, the second metal layer, and the third metal layer are formed within each damascene pattern.

17. The method of claim 14, wherein the second metal layer has a height which is approximately 10% to 20% lower than a height of the damascene patterns.

18. The method of claim 7, wherein the second metal layer is formed from aluminum (Al).

19. The method of claim 7, wherein the second metal layer is formed to have a thickness of approximately 200 to 300 angstroms.

20. The method of claim 7, wherein the second metal layer is formed by a chemical vacuum deposition (CVD) method.

21. The method of claim 7, wherein the third metal layer is formed to have a thickness of approximately 1000 to 2000 angstroms.

22. The method of claim 7, further comprising forming a capping layer over the insulating layer before the formation of the damascene patterns.
